(19) United States
(12) Patent Application Publication
(10) Pub. No.: US 2022/0357363 A1
(43) Pub. Date: Nov. 10, 2022

(54) MEASUREMENT INSTRUMENT AND METHOD FOR ACQUIRING AN INPUT SIGNAL

(71) Applicant: Rohde & Schwarz GmbH & Co. KG, Munich (DE)

(72) Inventors: Andrew Schaefer, Munich (DE); Cornelius Kaiser, Munich (DE)

(73) Assignee: Rohde & Schwarz GmbH & Co. KG, Munich (DE)

(21) Appl. No.: 17/306,306

(22) Filed: May 3, 2021

(51) Int. Cl. G01R 13/02; G01R 23/165

(52) U.S. Cl. CPC G01R 13/0272; G01R 23/165

(57) ABSTRACT

A measurement instrument for acquiring an input signal is described. The measurement instrument includes a first acquisition path with a first acquisition circuit having a first sampling rate. The measurement instrument includes at least one second acquisition path with a second acquisition circuit, having a second sampling rate. The measurement instrument is configured to acquire the input signal with an overall sampling rate being higher than the first sampling rate and the second sampling rate. The first acquisition path and the at least one second acquisition path each have a decimation filter and a decimator connected in series to the decimation filter, thereby equalizing a low frequency band in the input signal when processing the input signal. Further, method of acquiring an input signal is described.

### FIELD OF THE DISCLOSURE

Embodiments of the present disclosure relate generally to a measurement instrument for acquiring an input signal. Further, embodiments of the present disclosure relate to a method of acquiring an input signal.

### BACKGROUND

In the state of the art, measurement instruments like oscilloscopes are known that are used to acquire an input signal. Modern measurement instruments, also called high performance measurement instruments, are enabled to process high data rates, e.g. up to 320 Giga samples per second (GS/s). Accordingly, these high performance measurement instruments typically comprise multiple acquisition paths provided by separately formed chips, for instance multiple application-specific integrated circuits (ASICs) that are used for acquiring the input signal appropriately. In other words, the data acquisition of the input signals with high data rates is spread amongst multiple chips or rather circuits. Hence, a multiple path acquisition is provided by the high performance measurement instruments.

However, the high performance measurement instruments still struggle with diverse challenges concerning digital signal processing architectures, for instance digital triggering. A further important task relates to the compensation of low frequency (LF) responses, which is also known as droop compensation. So far, no solution is known for performing a low frequency response compensation in a multiple path acquisition, particularly in real time.

Accordingly, there is a need for a measurement instrument as well as a method, enabling low frequency equalization while ensuring high data acquisition rates simultaneously.

### SUMMARY

Embodiments of the present disclosure provide a measurement instrument of acquiring an input signal. In an embodiment, the measurement instrument comprises a first acquisition path with a first acquisition circuit that has a first sampling rate as well as at least one second acquisition path with a second acquisition circuit that has a second sampling rate. The measurement instrument is configured to acquire the input signal with an overall sampling rate that is higher than the first sampling rate and higher than the second sampling rate. The first acquisition path and the at least one second acquisition path each have a decimation filter and a decimator connected in series to the decimation filter, thereby equalizing a low frequency band in the input signal when processing the input signal.

Further, embodiments of the present disclosure provide a method of acquiring an input signal. In an embodiment, the method comprises the steps of:

Acquiring the input signal with a first sampling rate within a first acquisition path by the first acquisition circuit,

Acquiring the input signal with a second sampling rate within at least one second acquisition path by a second acquisition circuit.

The measurement instrument acquires the input signal with an overall sampling rate that is higher than the first sampling rate and the second sampling rate. The first acquisition path and the at least one second acquisition path each equalize a low frequency band in the input signal by a decimator connected in series to a decimation filter within the acquisition path when processing the input signal.

The main idea relates to a real time compensation of low frequency response, namely a real time compensation in the low frequency range, even though acquisition of the input signal is spread over multiple acquisition paths, namely the first acquisition path and the at least one second acquisition path. For instance, in total four different acquisition paths may be provided, which may relate to reverse traffic channels (RTCHs).

Accordingly, the measurement instrument has a high performance since the data acquisition is spread amongst several acquisition paths, each having a corresponding acquisition circuit with a respective sample rate, wherein the overall sample rate of the measurement instrument is higher than the individual sample rate of a single acquisition channel Hence, it is ensured that input signals with high data rates can be acquired appropriately.

In addition, the measurement instrument is enabled for a droop compensation, namely a low frequency response compensation.

This can be achieved, for example, by the specific architecture of the measurement instrument that comprises, for example, at least two different acquisition paths with separately formed acquisition circuits. In addition, each of the acquisition paths comprises, for example, the decimation filter connected in series to the decimator, which together decimate the respective signal received such that a decimated output signal is provided that can be processed for equalizing a low frequency band in the input signal, thereby ensuring the droop compensation. Since the input signal is processed by the decimation filter and the decimator connected in series thereto, a real-time low frequency response compensation is implemented in the multiple path acquisition.

In some embodiments, the respective acquisition circuits may be implemented by an application-specific integrated circuit (ASIC), a field-programmable gate array (FPGA) or any other suitable circuit, chip design, etc. The circuit may be implemented on a (separate) chip that is configured to also perform additional signal processing tasks like triggering, e.g., by a triggering circuit implemented on the chip.

Generally, data can be acquired in real-time by the acquisition circuits.

The decimation filters provided in each of the acquisition paths correspond to low pass filters. Hence, a low pass filtering is distributed among the several acquisition paths since the decimation filters are provided in each of the acquisition paths.

The decimators perform a decimation of the input signal, namely a down-sampling of the input signal. Hence, the data rate is reduced significantly such that a subsequent low frequency

Moreover, the different acquisition paths may be provided in a so-called time-interleaved manner, as each of the acquisition paths receive the input signal in a phase-shifted manner (time-interleaving) such that a phase-shifted acquisition/sampling can be done by the different acquisition paths in the time-interleaved acquisition architecture.

Therefore, an efficient equalization of low frequency effects in the time-interleaved acquisition architecture is established, wherein decimators and distributed decimator filters, namely the distributed low pass filters, are provided in each of the time-interleaved acquisition paths of the time-interleaved acquisition architecture.

An aspect provides that the respective decimation filters comprise distributed low pass filters. Hence, a resource optimization is provided as the decimation functionality is distributed among the several low pass filters that are distributed. In general, a 1/N part of the total impulse response is implemented by each of the N low pass filters respectively.

The decimation filters, namely the distributed low pass filters, may be established by a decimating cascaded integrator-comb filter, namely a decimating CIC filter. Each of the respective distributed low pass filters, e.g. the decimating CIC filter, may be defined as follows:

$$H ( z ) = {( \frac{1 - {z}^{- RM}}{1 - {z}^{- 1}} )}^{N} = {( {\sum }_{k = 0}^{RM - 1} {z}^{- k} )}^{N} ,$$

wherein R corresponds to a decimation or interpolation ratio, M corresponds to a number of samples per stage, and N corresponds to the number of stages in the filter.

Another aspect provides that the measurement instrument has an adder that is associated with the decimators of the acquisition paths, wherein the adder adds decimated output signals of the decimators, thereby providing an added signal. The added signal corresponds to the sum of the decimated signals outputted by the decimators of each acquisition path. Accordingly, the added signal is reduced with regard to the data rate. In other words, the added signal corresponds to a down-sampled signal with respect to the input signal. The added signal may be used for further processing, for example in a post-processing module.

For instance, the measurement instrument has at least one low frequency equalization filter receiving the added signal for conducting a low frequency band equalization. The low frequency equalization filter processes the added signal obtained from the adder in order to perform the low frequency equalization. The low frequency equalization filter receives the added signal that is obtained from the previously decimated output signals, thereby ensuring that the low frequency equalization filter is enabled to process the added signal appropriately.

The front end of the measurement instrument is typically measured during the manufacturing of the measurement instrument. The resulting frequency response is used to set the low frequency equalization filter coefficients so that the low frequency equalization filter is enabled to equalize the frequency response.

The low frequency equalization filter may be established by an infinite impulse response (IIR) filter. Alternatively, a finite impulse response (FIR) filter is provided. FIR and IIR filters relate to the two major classifications of digital filters used for signal filtration. The FIR filter provides an impulse response of a finite period, whereas the IIR filter is a type of filter that generates an impulse response of infinite duration for a dynamic system. In some embodiments, the IIR filter also takes (previous) output samples into account by a feedback, whereas the FIR filter does not have a feedback.

The low frequency equalization filter may provide a filter output signal. The filter output signal may be further processed by a subsequent post-processing module that is used for compensating the low frequency response appropriately.

The measurement instrument may comprise a memory, such as a memory circuit, associated with the low frequency equalization filter, wherein the memory is configured to store the filter output signal. In an embodiment, the memory may include random access memory (RAM). The memory may be directly connected with the low frequency equalization filter such that the memory directly receives the filter output signal provided by the low frequency equalization filter.

Prior to storing the filter output signal in the memory, a decimation or interpolation of the filter output signal may take place. In general, this relates to a tradeoff between accuracy and data amount.

Further, the measurement instrument may be configured to equalize a digitized input signal based on the filter output signal. The measurement instrument may comprise a post-processing circuit or module that receives the filter output signal, for example the one stored in the memory. The post-processing module may be configured to access the memory for retrieving the filter output signal. In the post-processing module, the filter output signal obtained as well as the acquired input signals forwarded to the post-processing module by the different acquisition paths are processed commonly in order to equalize the digitized input signal appropriately, namely equalizing the low frequency band in the input signal.

In other words, the filter output signal is up-sampled, e.g. interpolated, and added to the data streams provided by the different acquisition paths.

The at least one low frequency equalization filter is a common low frequency equalization filter that is provided for the different acquisition paths commonly. Hence, the low frequency equalization filter may be provided only once such that it is not necessary to provide several low frequency equalization filters for each of the different acquisition paths since the acquisition paths share the common low frequency equalization filter. Thus, resources can be saved, thereby providing a cost-efficient measurement instrument with regard to the filter implementation.

In other words, a single low frequency equalization filter is provided that is associated with all acquisition paths.

The at least one low frequency equalization filter may be established on a separate circuit, e.g., chip, with respect to the acquisition paths. The separate chip may comprise a field-programmable gate array (FPGA), which is connected with the separately formed acquisition paths, for example the respective chips or rather the application-specific integrated circuits (ASICs).

Another aspect provides that the at least one low frequency equalization filter is established on a circuit, e.g., chip, on which at least one acquisition path is also established. Thus, the at least one low frequency equalization filter and one of the acquisition paths are provided on a common chip.

The measurement instrument may comprise a post-processing circuit or module that is connected with the at least one low frequency equalization filter and the acquisition paths. The post-processing module may be established by a combination of hardware and software circuitry, wherein the data streams received are processed by the post-processing module in order to provide an output signal.

The post-processing module may be configured to process a filter output signal of the at least one low frequency equalization filter and the acquired signals of the acquisition paths in a synchronized manner, thereby providing an equalized output signal. The post-processing module receives the different data streams, namely the acquired signals as well as the filter output signal. The filter output signal is up-sampled previously such that the up-sampled filter output signal can be added to the acquired signals, thereby providing the equalized output signal, namely the output signal with equalized low frequency band.

According to a further aspect, the acquisition paths are established in hardware, for example by application-specific integrated circuits (ASICs). Hence, a real-time processing of the input signals during acquisition is ensured.

Moreover, the low frequency equalization filter is also established in hardware, thereby ensuring a real-time processing. For instance, the low frequency equalization filter is provided by a field-programmable gate array (FPGA). Alternatively, the low frequency equalization filter is implemented in one of the application-specific integrated circuits (ASICs) that provide the respective acquisition paths.

In some embodiments, the post-processing module may be established by a field-programmable gate array (FPGA) in combination with software.

In some embodiments, the FPGA providing the post-processing module may also comprise the low frequency equalization filter that is established by hardware purely.

The decimator filters may comprise a distributed periodic time variant filter for compensating frequency mismatches. In some embodiments, the distributed periodic time variant filter is configured to compensate a mismatch between a transfer function associated with the first acquisition path and a transfer function associated with the second acquisition path, for example based on digital output signals provided by the respective acquisition paths. The frequency mismatches to be compensated typically take place between the analog parts of the acquisition paths.

The distributed periodic time variant filter may be established as a linear periodic time variant (LPTV) filter.

The compensation of the frequency mismatches relate to an interleave alignment, which may take place in a post-processing.

The time-interleaved architecture used by the measurement instrument causes frequency response differences that have to be compensated additionally, e.g., by an interleave alignment. This alignment essentially takes place in a post-processing. Since a strong decimation of the input signal takes place anyway, an interleave alignment of the low frequency band can also be done in hardware, namely in real-time.

Another aspect provides that the sum of the first sampling rate of the first acquisition circuit and the second sampling rate of the at least one second acquisition circuit equals the overall sampling rate. Accordingly, the overall sampling rate of the measurement instrument is distributed over the different acquisition paths, which have their own sampling rate being lower than the one of the entire measurement instrument. However, the sampling rates of the individual acquisition paths together establish the overall sampling rate of the measurement instrument.

Another aspect provides that the first sampling rate and the second sampling rate are equal. Therefore, the different acquisition paths have the same sampling rate. In some embodiments, each of the different acquisition paths, for example in case of more than two acquisition paths, e.g., four acquisition paths, may have the same sampling rate, thereby ensuring that the respective acquisition paths each acquire a similar amount of samples.

The first acquisition circuit and the at least one second acquisition circuit may be provided on separately formed chips. In some embodiments, the respective acquisition circuits are implemented on separate chips.

In some embodiments, the first acquisition circuit may be established by an application-specific integrated circuit (ASIC) or a field-programmable gate array (FPGA) and/or wherein the second acquisition circuit is established by an application-specific integrated circuit (ASIC) or a field-programmable gate array (FPGA). Thus, the respective circuits may relate to integrated circuits (ICs).

For instance, the respective decimator connected in series with the decimation filter may have a decimation factor or rather decimation ratio of 64, thereby ensuring that a subsequent low frequency equalization filter is enabled to process the decimated output signal. Furthermore, this ensures that the data associated with the decimated output signals can be exchanged among the different acquisition paths, for example the acquisition circuits, e.g., the application-specific integrated circuits (ASICs).

Generally, a real-time droop compensation, namely a low-frequency (LF) response compensation, is implemented in the multiple path acquisition. In some embodiments, each acquisition path comprises a respective decimation filter and a respective decimator connected with the decimation filter such that the decimated output signals are provided for each acquisition path. These decimated output signals have a reduced data rate such that they can be processed by the low frequency compensation filter appropriately, for example the infinite impulse response (IIR) filter. Alternatively, a finite impulse response (FIR) filter may be used. Previously, the decimated output signals were summed by the adder such that the added signal is obtained that is forwarded to the low frequency compensation filter. Thus, the real-time correction can be ensured even though the input signals has a high data rate, e.g., a data rate of 320 GS/s.

In other words, a decimated data stream is obtained, e.g., the added signal, which can be processed by the low frequency compensation filter, for example in real-time.

The low frequency compensation filter processes the added signal received appropriately while outputting the filter output signal that is forwarded to the post-processing module that also receives the acquired decimated input signals from the different acquisition paths. Previously, the filter output signal has been interpolated by the cascaded integrator-comb interpolator circuit in order to increase the sampling rate.

The decimation filter together with the respective decimator per acquisition path corresponds to a decimator module such that each acquisition path has one decimator module, wherein the decimator modules of the acquisition paths are connected with the low frequency compensation filter. In addition, an interpolator module is provided that comprises the cascaded integrator-comb interpolator circuit, namely the circuit comprising the cascaded integrator-comb (CIC) filter and the interpolator.

Accordingly, each of the acquisition paths performs a part of the overall decimation filtering due to the decimator filters and subsequent filters provided within each acquisition path.

The acquisition paths may be interconnected with each other such that the respective decimated output signal of one acquisition path is forwarded to a next acquisition path, thereby obtaining the added signal at the end of the cascade. Alternatively, the acquisition paths are connected with a separately formed circuit, e.g. an application-specific integrated circuit (ASIC), that receives the decimated output signals provided by the decimators while processing the decimated output signals, namely adding the decimated output signals in order to generate the added signal. Hence, the adder may be implemented by each of the acquisition paths partly or rather by a separately formed circuit, e.g. on a separately formed chip.

The added signal is processed by the low frequency compensation filter, thereby generating the filter output signal, which corresponds to the output signal of the correction path. The filter output signal is acquired as a further data stream in parallel with the acquisition of the data processed by the acquisition paths.

In the post-processing step, also called enhancement, the filter output signal is interpolated back to the required data rate, e.g., the one of the input signal, and combined with the acquired signals, thereby achieving the low frequency corrected signal.

In some embodiments, the term “module” refers to or includes, inter alia, a combination of hardware (e.g. a processor such as an integrated circuit or other circuitry) and software (e.g. machine- or processor-executable instructions, commands, or code such as firmware, programming, or object code). Furthermore, a combination of hardware and software may include hardware only (i.e. a hardware element with no software elements), software hosted at hardware (e.g. software that is stored at a memory and executed or interpreted at a processor), or hardware with the software hosted thereon. In some embodiments, the hardware may, inter alia, comprise a CPU, a GPU, an FPGA, an ASIC, or other types of electronic circuitry.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows an overview of a measurement instrument according to an embodiment of the present disclosure;

FIG. 2 schematically shows an overview of a representative decimation filter used by the measurement instrument according to an embodiment of the present disclosure; and

FIG. 3 schematically shows an overview illustrating the distributed decimation filter architecture.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed. Similarly, any steps described herein may be interchangeable with other steps, or combinations of steps, in order to achieve the same or substantially similar result. Moreover, some of the method steps can be carried serially or in parallel, or in any order unless specifically expressed or understood in the context of other method steps.

In the foregoing description, specific details are set forth to provide a thorough understanding of exemplary embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein.

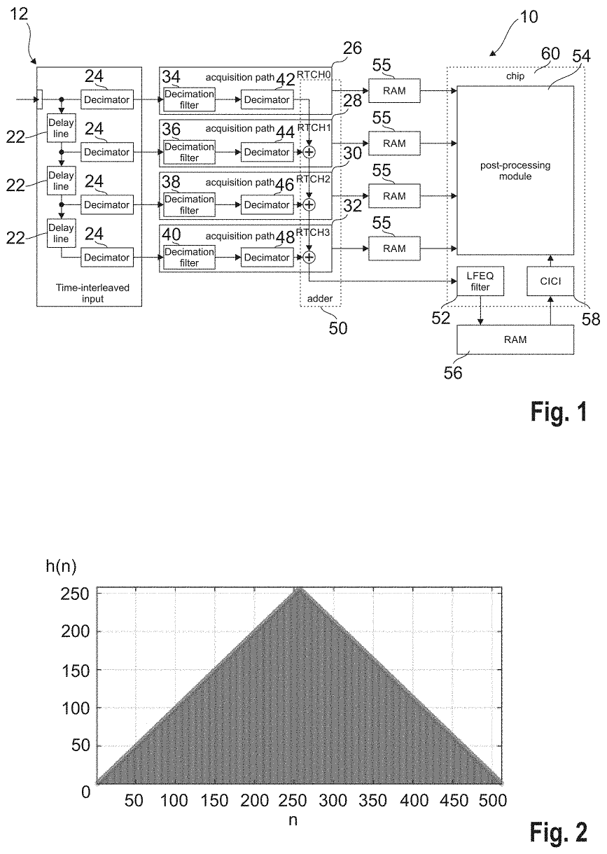

FIG. 1 schematically shows a measurement instrument 10 that may be established, for example, as an oscilloscope. The measurement instrument 10 has an input 12 for receiving an input signal with a certain data rate. The input signal may have a data rate of 320 GS/s.

The input 12, which is illustrated by the dashed lines, is established as a time-interleaved input that spreads the input signal across multiple acquisition paths 14, 16, 18, 20 by using delay lines 22 between adjacent acquisition paths 14-20. The acquisition paths 14-20 are labelled by RTCH0-RTCH3 in the shown embodiment since the acquisition paths 14-20 may be established by Reversed Traffic Channels.

Besides the delay lines 22, the input 12 also comprises decimators 24 associated with the acquisition paths 14-20 in order to reduce the data rate and to establish a time-interleaved acquisition architecture. The decimators 24 may have a decimation factor of 4 such that the acquisition paths 14-20 each have a sampling rate of 80 GS/s. Hence, the sum of the sampling rates of the acquisition paths 14-20 equals an overall sampling rate of the measurement instrument, namely 320 GS/s that corresponds to the data rate of the input signal. Moreover, the different acquisition paths 14-20 have an equal sampling rate, namely 80 GS/s. Accordingly, each of the acquisition paths 14-20 receives a decimated input signal that has been processed by a corresponding decimator 24 previously.

In some embodiments, the acquisition paths 16-20 each comprise a delayed and decimated input signal, as the input signal has been previously delayed by the respective delay lines 22.

In the shown embodiment, four acquisition paths 16-20 are provided such that three delay lines 22 are provided. The decimators 24 associated with the input 12 have a decimation factor or rather decimation ratio of 4 that corresponds to the number of acquisition paths 16-20, thereby ensuring the time-interleaved acquisition architecture.

The acquisition paths 14-20 each comprise a respective acquisition circuit 26-32 that is implemented, for example, on a certain chip. For instance, the acquisition circuits 26-32 may be established by application-specific integrated circuits (ASICs). Alternatively, the acquisition circuits 26-32 are established by field-programmable gate arrays (FPGAs). Hence, the acquisition circuits 26-32 may be implemented by integrated circuits (ICs). However, the acquisition paths 14-20, for example the respective acquisition circuits 26-32, may be provided on separately formed circuits, e.g., chips.

As shown in FIG. 1, each of the acquisition circuits 26-32 comprise a decimation filter 34-40 as well as a decimator 42-48 that is connected in series with the decimation filter of the respective acquisition path 14-20. Hence, a distributed filter architecture is established, wherein the decimation filters 34-40 correspond to low pass filters. Thus, distributed low pass filters are provided. In FIG. 2, a respective overview of an exemplary distributed low pass filter is provided.

The decimators 42-48 of the respective acquisition paths 14-20 may have a decimation factor of 64. Therefore, the data rate of the input signal corresponds to 320 GS/s, whereas the decimated output signal of the corresponding decimator 42-48 relates to 1.25 GS/s such that the decimation factor or rather decimation ratio is 256. For instance, two stages may be provided, wherein one sample per stage is processed. In other words, a two-tap decimation filter, e.g., a 2-tap finite impulse response (FIR) filter with constant coefficients is provided.

Generally, the decimation filters 34-40 together with the subsequent decimators 42-48 correspond to a decimating cascade-integrator comb (CIC) filter.

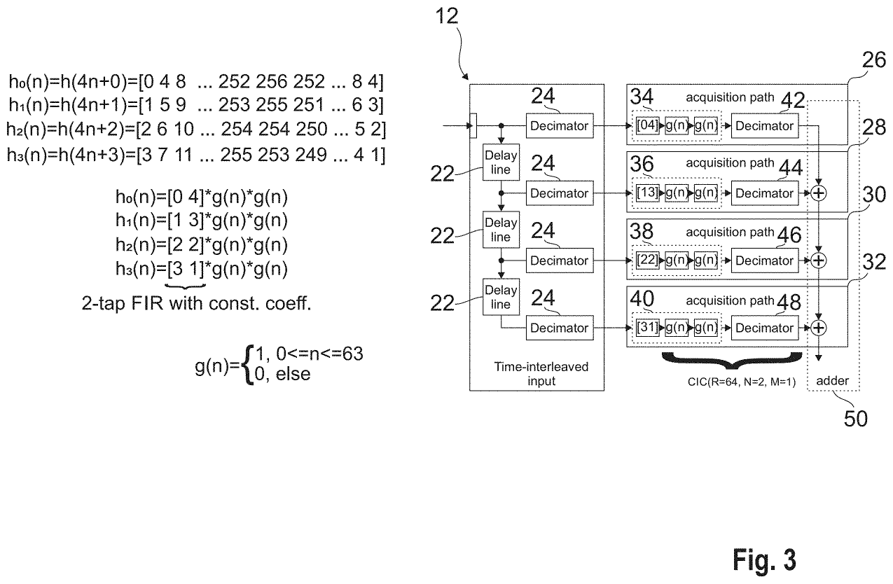

The respective concept is illustrated in FIG. 3, wherein each of the respective distributed low pass filters, e.g. the decimating CIC filter, may be defined as follows:

$$H ( z ) = {( \frac{1 - {z}^{- RM}}{1 - {z}^{- 1}} )}^{N} = {( {\sum }_{k = 0}^{RM - 1} {z}^{- k} )}^{N} ,$$

wherein R corresponds to a decimation or interpolation ratio, M corresponds to a number of samples per stage, and N corresponds to the number of stages in the filter.

Generally, the decimators 42-48 process the filtered input signals, thereby providing decimated output signals for further processing.

The respective decimators 42-48 are connected with an adder 50 that adds the decimated output signals provided by the decimators 42-48, thereby providing an added signal.

In the shown embodiment, the adder 50, which is associated with the decimators 42-48 of the acquisition paths 14-20, is provided in a distributed manner, as the acquisition circuits 14-18 forward their decimated output signals to the respective next acquisition circuit 16-20 such that the added signal is provided by the last acquisition circuit 20. Alternatively, the adder 50 may be established on a separate circuit, e.g., chip, that is connected with all of the acquisition circuits 14-20 such that the decimated output signals of all acquisition circuits 14-20 is received and processed by the separately formed adder 50 that provides the added signal for further processing.

The added signal is forwarded to a low frequency equalization (LFEQ) filter 52 that conducts a low frequency band equalization on the added signal obtained. The low frequency equalization filter 52 may be established by an infinite impulse response (IIR) filter or rather a finite impulse response (FIR) filter. In any case, the low frequency equalization filter 52 receives a signal with a data rate significantly reduced compared to the data rate of the input signal, namely the added signal, as well as the output signals of the acquisition paths. In some embodiments, the added signal also has a data rate of 1.25 GS/s similar to the one of the decimated output signals of the respective decimators 42-48, whereas the input signal has a data rate of 320 GS/s, and wherein the acquisition paths 14-20 each provide an output signal with a data rate of 80 GS/s, as four acquisition paths 14-20 are provided. The low frequency equalization filter 52 processes the added signal while outputting a filter output signal that is used for further processing.

The measurement instrument 10 further comprises a post-processing module 54 that is connected with the different and separately formed acquisition paths 14-20 while receiving the output signals of the acquisitions paths 14-20 as shown in FIG. 1. Optionally, random access memories (RAM) 55 are interconnected between the post-processing module 54 and the acquisition paths 14-20. In addition, the post-processing module 54 also receives the filter output signal of the low frequency equalization filter 52. In some embodiments, the post-processing module 54 includes circuitry configured for carrying out some of or all of its functionality described herein.

The measurement instrument 10 also comprises at least one memory 56, such as a memory circuit, that is interconnected between the post-processing module 54 and the low frequency equalization filter 52. The memory 56 may be established by a random-access memory (RAM). Hence, the filter output signal may be stored previously prior to being post-processed by the post-processing module 54. Moreover, the filter out signal may be decimated or rather interpolated prior to being stored in the memory 56.

The measurement instrument 10 further may comprise an up-sampling circuit 58, for instance a cascaded integrator-comb interpolator (CICI) circuit. The up-sampling circuit 58 receives the filter output signal, for example from the memory 56. The up-sampling circuit 58 interpolates the filter output signal such that the post-processing module 54 receives a signal with the data rate of the input signal. Hence, the post-processing module 54 is enabled to add the up-sampled filter output signal to the output signals of the different acquisition paths 14-20.

The low frequency equalization filter 52 is a common low frequency equalization filter that is provided for the different acquisition paths 14-20 simultaneously, as the low frequency equalization filter 52 receives the added signal provided by the adder 50 that sums the decimated output signals of the decimators 42-48 of the individual acquisition paths 14-20.

Thus, the low frequency equalization filter 52 is associated with each of the individual acquisition paths 14-20 such that resources can be saved since the single low frequency equalization filter 52, which is established on a separate chip with respect to the acquisition paths 14-20, is sufficient for performing the low frequency response equalization on the input signal.

Accordingly, the measurement instrument 10 is generally configured to equalize a digitized input signal based on the filter output signal. The equalization is done by the post-processing module 54.

In some embodiments, the post-processing module 54 is provided on a separate circuit, e.g., chip, with respect to the acquisition paths 14-20.

In the embodiment shown in FIG. 1, the post-processing module 54 and the low frequency equalization filter 52 together are implemented on a common chip 60, for instance by a field-programmable gate array (FPGA). The several different acquisition paths 14-20 each are also implemented on different chips, for instance by application-specific integrated circuits (ASICs).

In some embodiments, the post-processing module 54 is established in hardware and software, whereas the acquisition paths 14-20 and the low frequency equalization filter 52 are established in hardware solely, thereby ensuring a real-time processing.

Furthermore, the decimator filters 34-40 may comprise a distributed periodic time variant filter for compensating frequency mismatches that take place between analog parts of the acquisition paths 14-20. In some embodiments, the distributed periodic time variant filter is configured to compensate a mismatch between transfer functions associated with different acquisition paths 14-20, for example based on digital output signals provided by the respective acquisition paths 14-20.

Certain embodiments disclosed herein, for example the respective module(s), filters, other electrical components, etc., utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes one or more processors or portions thereof and accompanying software, firmware, hardware, and the like.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A measurement instrument for acquiring an input signal, the measurement instrument comprising:
a first acquisition path with a first acquisition circuit, the first acquisition circuit having a first sampling rate; and
at least one second acquisition path with a second acquisition circuit, the second acquisition circuit having a second sampling rate;
wherein the measurement instrument being configured to acquire the input signal with an overall sampling rate, the overall sampling rate being higher than the first sampling rate, the overall sampling rate being higher than the second sampling rate, and
wherein the first acquisition path and the at least one second acquisition path each having a decimation filter and a decimator connected in series to the decimation filter, thereby equalizing a low frequency band in the input signal when processing the input signal.

2. The measurement instrument according to claim 1, wherein the respective decimation filters comprise distributed low pass filters.

3. The measurement instrument according to claim 1, wherein the measurement instrument has an adder that is associated with the decimators of the acquisition paths, and wherein the adder adds decimated output signals of the decimators, thereby providing an added signal.

4. The measurement instrument according to claim 3, wherein the measurement instrument has at least one low frequency equalization filter receiving the added signal for conducting a low frequency band equalization.

5. The measurement instrument according to claim 4, wherein the low frequency equalization filter is established by an infinite impulse response (IIR) filter.

6. The measurement instrument according to claim 4, wherein the low frequency equalization filter provides a filter output signal.

7. The measurement instrument according to claim 6, wherein the measurement instrument comprises a memory associated with the low frequency equalization filter, and wherein the memory is configured to store the filter output signal.

8. The measurement instrument according to claim 6, wherein the measurement instrument is configured to equalize a digitized input signal based on the filter output signal.

9. The measurement instrument according to claim 4, wherein the at least one low frequency equalization filter is a common low frequency equalization filter that is provided for the different acquisition paths commonly.

10. The measurement instrument according to claim 4, wherein the at least one low frequency equalization filter is established on a separate chip with respect to the acquisition paths.

11. The measurement instrument according to claim 4, wherein the at least one low frequency equalization filter is established on a chip on which at least one acquisition path is also established.

12. The measurement instrument according to claim 4, wherein the measurement instrument comprises a post-processing module that is connected with the at least one low frequency equalization filter and the acquisition paths.

13. The measurement instrument according to claim 12, wherein the post-processing module is configured to process a filter output signal of the at least one low frequency equalization filter and the acquired signals of the acquisition paths in a synchronized manner, thereby providing an equalized output signal.

14. The measurement instrument according to claim 1, wherein the acquisition paths are established in hardware circuitry.

15. The measurement instrument according to claim 1, wherein the decimator filters comprise a distributed periodic time variant filter for compensating frequency mismatches.

16. The measurement instrument according to claim 1, wherein the sum of the first sampling rate of the first acquisition circuit and the second sampling rate of the at least one second acquisition circuit equals the overall sampling rate.

17. The measurement instrument according to claim 1, wherein the first sampling rate and the second sampling rate are equal.

18. The measurement instrument according to claim 1, wherein the first acquisition circuit and the at least one second acquisition circuit are provided on separately formed circuit chips.

19. The measurement instrument according to claim 1, wherein the first acquisition circuit is established by an application-specific integrated circuit or a field-programmable gate array and/or wherein the second acquisition circuit is established by an application-specific integrated circuit or a field-programmable gate array.

20. A method of acquiring an input signal, the method comprising:
acquiring the input signal with a first sampling rate within a first acquisition path by a first acquisition circuit;
acquiring the input signal with a second sampling rate within at least one second acquisition path by a second acquisition circuit,
wherein the measurement instrument acquiring the input signal with an overall sampling rate that is higher than the first sampling rate and the second sampling rate; and
the first acquisition path and the at least one second acquisition path each equalizing a low frequency band in the input signal by a decimator connected in series to a decimation filter within the acquisition paths when processing the input signal.
